(19) United States
(12) Patent Application Publication
(10) Pub. No.: US 2026/0291494 A1
(43) Pub. Date: Sep. 24, 2026

(54) HIGH-LINEARITY VOLTAGE-CONTROLLED CAPACITOR AND METHOD THEREOF

(71) Applicant: Realtek Semiconductor Corp., Hsinchu (TW)

(72) Inventor: Chia-Liang (Leon) Lin, Fremont, CA (US)

(21) Appl. No.: 19/087,664

(22) Filed: Mar. 24, 2025

(51) Int. Cl. H03K 17/56

(52) U.S. Cl. CPC H03K 17/56

(57) ABSTRACT

A voltage-controlled capacitor includes a first tunable capacitor positioned between a first node and a second node and configured to exhibit a first capacitance in accordance with a controlled voltage applied at the second node, and a second tunable capacitor positioned between the first node and the second node and configured to present a second capacitance in accordance with the controlled voltage, wherein each of the first tunable capacitor and the second tunable capacitor comprises a series connection of a capacitor and a varactor joined at a respective internal node that is DC (direct current) coupled to a respective bias node at which a respective bias voltage that is substantially stationary is applied.

### BACKGROUND OF THE DISCLOSURE

### Field of the Disclosure

The present disclosure generally relates to voltage-controlled capacitor, and particularly to voltage-controlled capacitor that can exhibit high linearity.

### Description of Related Art

Persons having ordinary skill in the art are familiar with terms and basic concepts related to microelectronics as used in this disclosure, such as “voltage,” “current,” “signal,” “noise,” “bias,” “AC (alternating current),” “DC (direct current)” “resistor,” “capacitor,” “capacitance,” “resistance,” “diode,” “impedance,” “CMOS (complementary metal-oxide semiconductor),” “NMOS (n-channel metal-oxide semiconductor) transistor,” and “PMOS (p-channel metal-oxide semiconductor) transistor.” These terms are used within the context of microelectronics, and the associated concepts are apparent to those skilled in the art, thereby obviating the need for a detailed explanation herein.

A MOS transistor, whether PMOS or NMOS, is said to be configured in a diode-connected topology when its gate is electrically connected to its drain terminal.

In the present disclosure, a signal is defined as a voltage of a variable level that carries specific information and may vary over time. The level of the signal at any given moment indicates its state at that moment.

A capacitor is a two-terminal device that allows a current to flow in and establish a voltage that is an integral of the AC current. The capacitance of the capacitor quantifies a rate of the change of the voltage in response to the current.

A tunable capacitor is a capacitor of a capacitance that can be controlled by a control signal. A voltage-controlled capacitor is a special type of tunable capacitor that can be controlled by a control voltage.

A “varactor” is a two-terminal device that exhibits a capacitance that is variable and determined by a voltage across its two terminals. Due to the variable capacitance nature, a varactor is widely used to embody a voltage-controlled capacitor.

As illustrated in FIG. 1A, a prior art voltage-controlled capacitor 100 comprises: a capacitor 111 characterized by a fixed capacitance, positioned between a first node 101 and a second node 102; a varactor 121 characterized by a variable capacitance, positioned between the second node 102 and a third node 103; and a resistor 131 disposed between the second node 102 and a fourth node 104. A voltage difference between the second node and the third node is denoted as V121. The third node 103 and the fourth node 104 are both low-impedance nodes, to which a control voltage and a bias voltage are respectively applied. When the resistor 131 exhibits a resistance substantially larger than an impedance of the varactor 121, the voltage-controlled capacitor 100 effectively becomes a series connection of the capacitor 111 and the varactor 121, with the capacitance determined by V121 that is dependent on both the bias voltage, which is generally static, and the control voltage, which is subject to dynamically varying. Consequently, the capacitance of the tunable capacitor 100 can be adjusted by the control voltage. The tunable capacitor 100 is well understood by those skilled in the art, and therefore, further detailed explanation is omitted herein for brevity.

The linearity of a voltage-controlled capacitor characterizes the variation of its capacitance in response to the control voltage. Ideally, an incremental change in the control voltage will lead to a proportional incremental change of its capacitance. In practice, a varactor typically exhibits poor linearity, as its capacitance tends to be minimal when the control voltage is low and saturates when the control voltage is high. FIG. 1B shows an exemplary curve of transfer characteristics of the voltage-controlled capacitor 100, wherein the horizonal axis is the control voltage and the vertical axis is its capacitance normalized with its maximum value. The curve is reasonably linear when the control voltage is between 0.3V and 0.7V, but the incremental change of capacitance in response to an incremental change of the control voltage is clearly diminishing when the control voltage rises above 0.7V or falls below 0.3V. In other words, the voltage-controlled capacitor has poor linearity when the control voltage is above 0.7V or below 0.3V.

What is desired is a voltage-controlled capacitor design that can exhibit significantly improved linearity.

### BRIEF DESCRIPTION OF THIS DISCLOSURE

An objective of the present invention is to utilize a combination of two tunable capacitors that are biased at two different bias voltages to achieve better linearity.

In one embodiment, the present disclosure provides a voltage-controlled capacitor comprising: a first tunable capacitor positioned between at a first node and a second node and configured to exhibit a first capacitance in accordance with a controlled voltage applied at the second node, and a second tunable capacitor positioned between the first node and the second node and configured to present a second capacitance in accordance with the controlled voltage, wherein each of the first tunable capacitor and the second tunable capacitor comprises a series connection of a capacitor and a varactor joined at a respective internal node that is DC (direct current) coupled to a respective bias node at which a respective bias voltage that is substantially stationary is applied.

In one embodiment, a method of capacitance control comprises: providing a tunable capacitor stencil comprising a series connection of an AC (alternating current) coupling capacitor and a varactor disposed between an input pin and a control pin, joined at an internal node coupled to a bias pin through a DC (direct current) coupling network; instantiating a first tunable capacitor based on the stencil, wherein the input pin, the control pin, and the bias pin are connected to an input node, a control node, and a first bias node, respectively; instantiating a second tunable capacitor based on the stencil, wherein the input pin, the control pin, and the bias pin are connected to the input node, the control node, and a second bias node, respectively; applying a first bias voltage to the first bias node; applying a second bias voltage to the second bias node; and applying a control voltage to the control node.

### BRIEF DESCRIPTION OF THE DRAWINGS

FIG. 1A shows a schematic diagram of a prior art voltage-controlled capacitor.

FIG. 1B shows an exemplary curve of transfer characteristics of the prior art voltage-controlled capacitor of FIG. 1A.

FIG. 2 shows a schematic diagram of a voltage-controlled capacitor in accordance with an embodiment of the present disclosure.

FIG. 3 shows exemplary curves of transfer characteristics of the voltage-controlled capacitor of FIG. 2.

FIG. 4 shows a flow diagram of a method of capacitance control in accordance with an embodiment of the present disclosure.

### DETAILED DESCRIPTION OF THIS DISCLOSURE

The present disclosure describes embodiments of voltage-controlled capacitors. While the specification describes several example embodiments of the disclosure considered favorable modes of practicing the invention, it should be understood that the invention can be implemented in many ways and is not limited to the particular examples described below or to the particular manner in which any features of such examples are implemented. In other instances, well-known details are not shown or described to avoid obscuring aspects of the disclosure.

This present disclosure is described from an engineering standpoint. For example, with reference to two variables, X and Y, when it is stated that “X is equal to Y,” it signifies that “X is approximately equal to Y,” denoting that “a difference between X and Y is within a specified engineering tolerance.” Similarly, when it is asserted that “X is zero,” it implies that “X is approximately zero,” meaning that “X is within a specified engineering tolerance.” The expression “X is substantially smaller than Y” denotes that “X is negligible with respect to Y,” indicating that “the ratio between X and Y is within a specified engineering tolerance, thereby rendering X negligible in comparison to Y.”

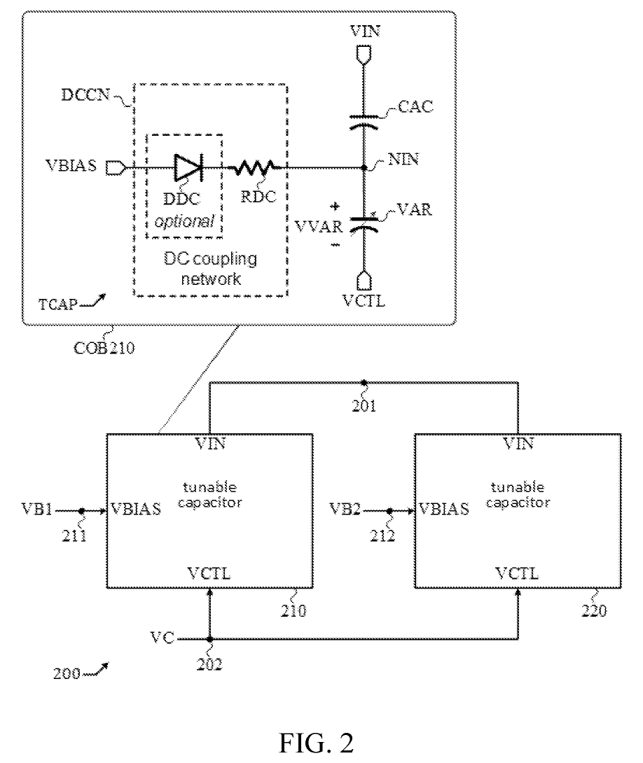

As illustrated in FIG. 2, a voltage-controlled capacitor 200 in accordance with the present disclosure comprises a first tunable capacitor 210 disposed between a first node 201 (which is also referred to as an input node) and a second node 202 (which is also referred to as a control node) and configured to exhibit a first capacitance in response to a control voltage VC applied at the second node 202, and a second tunable capacitor 220 disposed between the first node 201 and the second node 202 and configured to present a second capacitance in response to the control voltage VC. Each of the first tunable capacitor 210 and the second tunable capacitor 220 comprises a series connection of an AC (alternate current) coupling capacitor and a varactor coupled at a respective internal node that is DC (direct current) coupled to a respective bias node, at which a respective bias voltage is applied.

An exemplary tunable capacitor TCAP that one can use as a stencil and instantiate to embody the first tunable capacitor 210 and the second tunable capacitor 220 is shown in a callout box COB210. The exemplary tunable capacitor TCAP comprises an AC coupling capacitor CAC, a varactor VAR, and a DC coupling network DCCN. The exemplary tunable capacitor TCAP includes an input pin labeled as "VIN," a control pin labeled as "VCTL," and a bias pin labeled as "VBIAS." The AC coupling capacitor CAC is disposed between the input pin "VIN" and an internal node NIN. The varactor VAR is disposed between the control pin "VCTL" and the internal node NIN, and the DC coupling network DCCN is disposed between the bias pin "VBIAS" and the internal node NIN. When one instantiates the exemplary tunable capacitor TCAP to embody the first (second) tunable capacitor 210 (220), the input pin "VIN" is coupled to the first node 201, the control pin "VCTL" is coupled to the second node 202, and the bias pin "VBIAS" interfaces with a first (second) bias node 211 (212), at which a first (second) bias voltage VB1 (VB2) that is substantially stationary is applied. The DC coupling network DCCN comprises a series connection of a resistor RDC and a diode DDC that is optional and can be employed to reduce noise contribution of the DC coupling network DCCN. The principle of the noise reduction using the diode DDC is explained in a co-pending application of title “Low-noise tunable capacitor and method thereof” (Realtek docket number 114B-001US). Alternative embodiments of the DC coupling network DCCN that can preserve the advantage of noise reduction are also described in the co-pending application.

The impedance of the DC coupling network DCCN is substantially larger than the impedance of the varactor VAR at a frequency of interest. In an embodiment, “five times larger” can be considered “substantially larger.” As such, the exemplary tunable capacitor TCAP is approximately a series connection of the AC coupling capacitor CAC and the varactor VAR, the capacitance of which is determined by a voltage VVAR across the internal node NIN and the control pin “VCTL.” A DC level of the internal node NIN is equal to the bias voltage applied at the bias pin “VBIAS” offset by a threshold voltage of the diode DDC, if applicable. By applying a different bias voltage at the bias pin “VBIAS,” one can effectively adjust the voltage VVAR and offset transfer characteristics of the varactor VAR in response to the control voltage applied at the control pin “VCTL.”

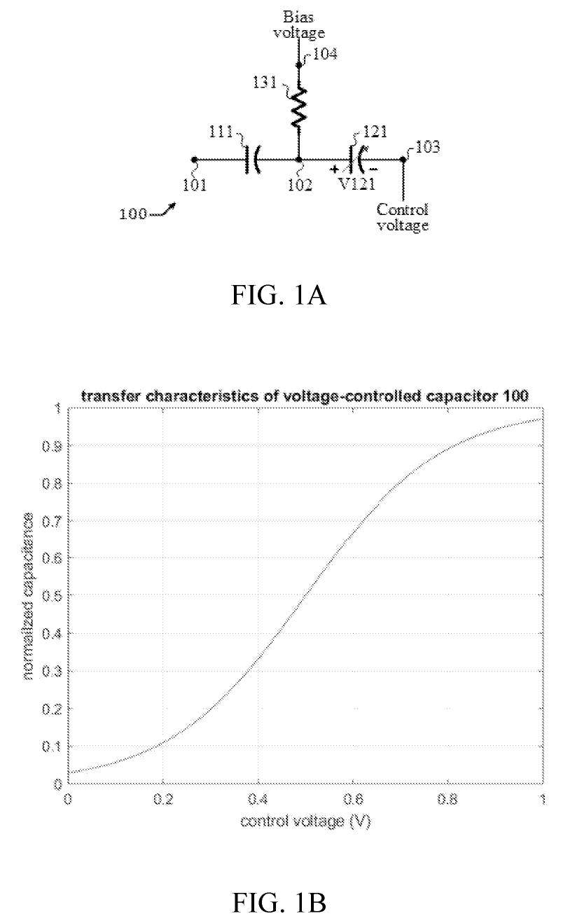

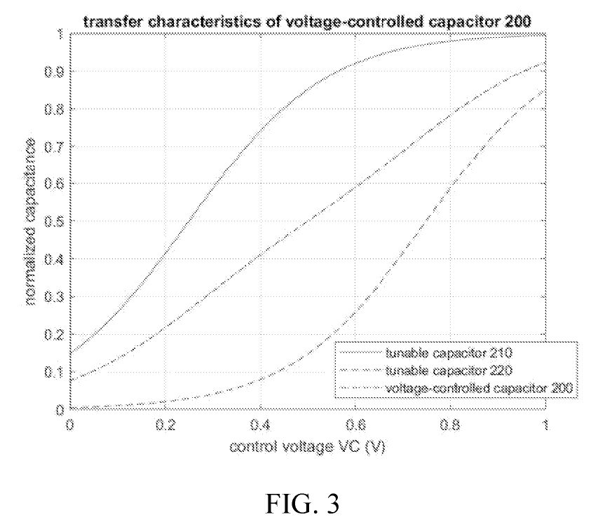

FIG. 3 shows three curves that correspond to transfer characteristics of the capacitance of the first tunable capacitor 210, the second tunable capacitor 220, and the voltage-controlled capacitor 200 (which is the combination of both tunable capacitors 210 and 220), respectively, in response to the control voltage VC. The horizontal axis is the control voltage VC, while the vertical axis corresponds to the respective capacitance normalized with its respective maximum value. The first tunable capacitor 210 uses a first bias voltage VB1 of 0.25V, and the second tunable capacitor 220 uses a second bias voltage VB2 of 0.75V, wherein a medium value 0.5V corresponds to the bias voltage of the prior art voltage-controlled capacitor 100 of FIG. 1A. As shown, the linearity of the first tunable capacitor 210 degrades severely when VC rises above 0.5V. Likewise, the linearity of the second tunable capacitor 220 degrades severely when VC falls below 0.5V. It is clear that the poor linearity of the first tunable capacitor 210 when VC is high is compensated by the second tunable capacitor 220, while the poor linearity of the second tunable 220 when VC is low is compensated by the first tunable capacitor 210. As a result, the voltage-controlled capacitor 200 has good linearity across the whole range of the VC between 0V and 1V. In conclusion, utilizing a combination of two tunable capacitors that are biased at two different bias voltages, one can effectively extend the linear range of the overall capacitance.

In one embodiment, the tunable capacitor 200 is fabricated using CMOS (complementary metal-oxide semiconductor) technology, wherein a diode may be implemented by configuring either a PMOS transistor or an NMOS transistor in a diode-connected topology, where the drain terminal and the gate terminal are electrically tied together. The "diode-connected" topology is well understood by those skilled in the art and thus does not require further explanation herein.

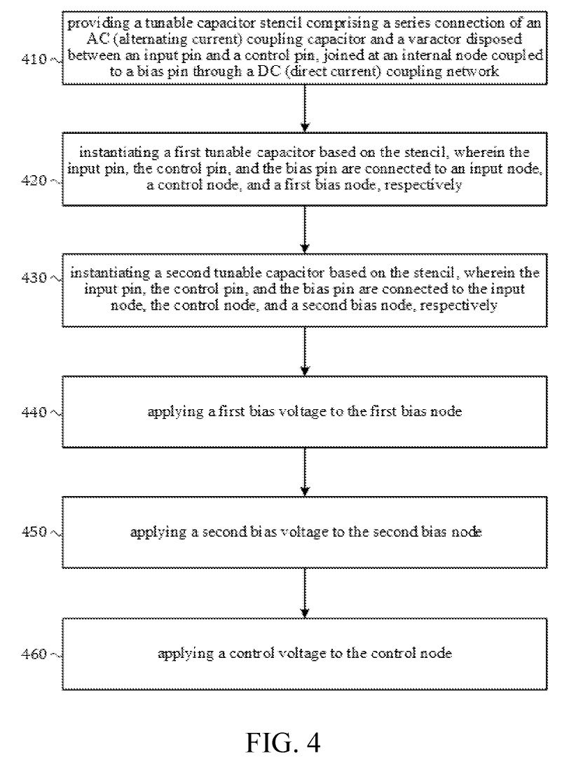

As illustrated in FIG. 4, a method of capacitance control comprises: (step 410) providing a tunable capacitor stencil comprising a series connection of an AC (alternating current) coupling capacitor and a varactor disposed between an input pin and a control pin, joined at an internal node coupled to a bias pin through a DC (direct current) coupling network; (step 420) instantiating a first tunable capacitor based on the stencil, wherein the input pin, the control pin, and the bias pin are connected to an input node, a control node, and a first bias node, respectively; (step 430) instantiating a second tunable capacitor based on the stencil, wherein the input pin, the control pin, and the bias pin are connected to the input node, the control node, and a second bias node, respectively; (step 440) applying a first bias voltage to the first bias node; (step 450) applying a second bias voltage to the second bias node; and (step 460) applying a control voltage to the control node.

Those skilled in the art will readily observe that numerous modifications and alterations of the device and method may be made while retaining the teachings of the disclosure. Accordingly, the above disclosure should not be construed as limited only by the metes and bounds of the appended claims.

What is claimed is:

1. A voltage-controlled capacitor comprising:
a first tunable capacitor positioned between a first node and a second node and configured to exhibit a first capacitance in accordance with a controlled voltage applied at the second node; and
a second tunable capacitor positioned between the first node and the second node and configured to present a second capacitance in accordance with the controlled voltage, wherein each of the first tunable capacitor and the second tunable capacitor comprises a series connection of a capacitor and a varactor joined at an internal node that is DC (direct current) coupled to a respective bias node at which a respective bias voltage that is substantially stationary is applied.

2. The voltage-controlled capacitor of claim 1, wherein the internal node is DC coupled to the respective bias node through a DC coupling network which comprises a resistor.

3. The voltage-controlled capacitor of claim 2, wherein an impedance of the resistor is substantially larger than an impedance of the varactor.

4. The voltage-controlled capacitor of claim 3, wherein the DC coupling network further comprises a diode connected in series with the resistor.

5. The voltage-controlled capacitor of claim 4, wherein the diode comprises a MOS (metal-oxide semiconductor) transistor configured in a diode-connected topology.

6. A method of capacitance control comprising:
providing a tunable capacitor stencil comprising a series connection of an AC (alternating current) coupling capacitor and a varactor disposed between an input pin and a control pin, joined at an internal node coupled to a bias pin through a DC (direct current) coupling network;
instantiating a first tunable capacitor based on the tunable capacitor stencil, wherein the input pin, the control pin, and the bias pin are connected to an input node, a control node, and a first bias node, respectively;
instantiating a second tunable capacitor based on the tunable capacitor stencil, wherein the input pin, the control pin, and the bias pin are connected to the input node, the control node, and a second bias node, respectively;
applying a first bias voltage to the first bias node;
applying a second bias voltage to the second bias node; and
applying a control voltage to the control node.

7. The method of capacitance control of claim 6, wherein the DC coupling network comprises a resistor.

8. The method of capacitance control of claim 7, wherein the DC coupling network further comprises a diode connected in series with the resistor.

9. The method of capacitance control of claim 7, wherein an impedance of the resistor is substantially larger than an impedance of the varactor.

10. The method of capacitance control of claim 6, wherein the first bias voltage and the second bias voltage are substantially stationary.
